(19) United States
(12) Patent Application Publication
(10) Pub. No.: US 2024/0258452 A1
(43) Pub. Date: Aug. 1, 2024

(54) Systems and Methods for Epitaxy-Free Thin-Film Solar Cells

(71) Applicant: California Institute of Technology, Pasadena, CA (US)

(72) Inventors: Phillip R. Jahelka, Altadena, CA (US); Andrew W. Nyholm, Pasadena, CA (US); Harry A. Atwater, South Pasadena, CA (US)

(73) Assignee: California Institute of Technology, Pasadena, CA (US)

(21) Appl. No.: 18/424,598

(22) Filed: Jan. 26, 2024

Related U.S. Application Data
(60) Provisional application No. 63/441,524, filed on Jan. 27, 2023.

(51) Int. Cl. H01L 31/18; H01L 31/0392; H01L 31/0693; H01L 31/0224; H01L 31/0304

(52) U.S. Cl. CPC H01L 31/1896; H01L 31/0392; H01L 31/0693; H01L 31/022425; H01L 31/03042; H01L 31/184

(57) ABSTRACT

Systems and methods for epitaxy-free thin-film solar cells are described. The thin-film solar cells can be fabricated with low cost epitaxy-free processes. The solar cells have high efficiency and are lightweight. These properties make the solar cells desired for space based solar cell applications.

### CROSS-REFERENCE TO RELATED APPLICATIONS

The current application claims the benefit under 35 U.S.C. § 119 (e) to U.S. Provisional Patent Application No. 63/441,524 entitled “Epitaxy-Free, Thin-Film GaAs Solar Cells Fabricated with Diffusion Doping and Mechanical Spalling” filed Jan. 27, 2023. The disclosure of U.S. Provisional Patent Application No. 63/441,524 is hereby incorporated by reference in its entirety for all purposes.

### FIELD OF THE INVENTION

The present invention generally relates to systems and methods for epitaxy-free, thin-film solar cells.

### BACKGROUND OF THE INVENTION

Epitaxy refers to a type of crystal growth or material deposition on a crystalline seed substrate, where the deposited crystalline layer is called an epitaxial film or epitaxial layer. Epitaxy is used in silicon-based manufacturing processes for bipolar junction transistors (BJTs) and modern complementary metal-oxide-semiconductors (CMOS), and is particularly important for compound semiconductors such as gallium arsenide (GaAs). Epitaxial layers (such as silicon and compound semiconductors) can be grown using vapor-phase epitaxy (VPE, a modification of chemical vapor deposition (CVD)), molecular-beam epitaxy (MBE), and so on. Although epitaxy can form uniform semiconductor layers with high purity which enable high efficiency in solar cells, the epitaxy processes can be costly (such as using expensive source materials, needing special equipment for operation, and environmental disposal costs can be high). Cost effective epitaxy-free methods to fabricate solar cells with desired efficiency are needed.

### BRIEF SUMMARY OF THE INVENTION

System and methods for epitaxy-free, thin-film solar cells are described. Many embodiments implement processes including (but not limited to) diffusion doping and mechanical spalling to fabricate thin-film solar cells such as (but not limited to) III-V solar cells. Such processes are epitaxy-free, where the growth of semiconductor crystalline layers is not needed. The epitaxy-free processes greatly reduce the production cost for making thin-film solar cells. The thin-film solar cells have reduced weight compared to the solar cells with thick substrates. The low-cost and lightweight solar cells have desired properties for various space applications.

Some embodiments include a method for fabricating a semiconductor device comprising:
forming a semiconductor layer on a semiconductor substrate via a diffusion doping process, wherein the semiconductor layer and the semiconductor substrate forms a p-n junction;
depositing a stress film on the semiconductor layer;
exfoliating a thin film by applying a pulling force to the stress film, wherein the thin film comprises the semiconductor layer and at least a portion of the semiconductor substrate;
depositing at least one electrode on the thin film to form an ohmic contact; and
etching a portion of the exfoliated thin film while preserving the stress film and the at least one electrode to form a semiconductor device.

In some embodiments, the semiconductor substrate comprises a material selected from the group consisting of: silicon, germanium, a III-V semiconductor, GaAs, GaP, InP, AlGaAs, GaInP, and GaAsP.

In some embodiments, the semiconductor substrate has a (110) orientation.

In some embodiments, the semiconductor substrate comprises an n-type semiconductor, and the semiconductor layer comprises a p-type semiconductor.

In some embodiments, the semiconductor substrate comprises a p-type semiconductor, and the semiconductor layer comprises an n-type semiconductor.

In some embodiments, the stress film comprises a metallic material selected from the group consisting of: nickel, chromium, and germanium.

In some embodiments, the thin film has a thickness less than or equal to 5 μm.

Some embodiments further comprise applying an adhesive tape to the stress film and pulling the adhesive tape to exfoliate the thin film.

In some embodiments, the adhesive tape comprises an acrylic glue or a silicone glue.

In some embodiments, the semiconductor substrate has a doping concentration less than or equal to 5×10¹⁷ cm⁻³; wherein the semiconductor layer has a doping concentration less than or equal to 5×10¹⁷ cm⁻³.

In some embodiments, the at least one electrode comprises a plurality of metal layers.

In some embodiments, the at least one electrode comprises at least one of: palladium, germanium, silver, indium, copper, tin, and gold.

In some embodiments, the diffusion doping process uses a sealed container with an inert gas; wherein the container comprises a refractory material.

Some embodiments further comprise annealing the at least one electrode to a temperature less than or equal to 200° C. to form the ohmic contact.

In some embodiments, the semiconductor substrate comprises n-GaAs, and the semiconductor layer comprises p-GaAs; wherein the diffusion doping processes uses a material comprising Zn as a dopant; wherein the stress film comprises nickel; wherein the at least one electrode comprises palladium, germanium, and gold.

In some embodiments, the etching step uses an etch solution comprising hydrogen peroxide and alkali hydroxide.

In some embodiments, the semiconductor device has an open circuit potential of at least 850 mV.

Some embodiments further comprise applying a second adhesive tape to the at least one electrode; removing the adhesive tape; and removing the stress film; and depositing a second set of electrodes onto the thin film.

Some embodiments include a solar cell comprising: an n-gallium arsenide (GaAs) substrate with a (110) orientation; a p-GaAs layer forming a junction with the n-GaAs substrate, wherein a thickness of the n-GaAs substrate and the p-GaAs layer is less than or equal to 5 μm; a plurality of electrodes deposited on the n-GaAs substrate, wherein each of the plurality of electrodes comprises a plurality of metal layers; and at least one electrode deposited on the p-GaAs layer.

In some embodiments, the n-GaAs substrate has a doping concentration less than or equal to 5×10¹⁷ cm⁻³, and the p-GaAs layer has a doping concentration less than or equal to 5×10¹⁷ cm⁻³; wherein the plurality of electrodes comprises at least one of: palladium, germanium, silver, indium, copper, tin, and gold; wherein the at least one electrode comprises at least one of: nickel, germanium, and chromium.

Some embodiments include a solar cell comprising: an n-gallium arsenide (GaAs) substrate with a (110) orientation; a p-GaAs layer forming a junction with the n-GaAs substrate, wherein a thickness of the n-GaAs substrate and the p-GaAs layer is less than or equal to 5 μm; a first set of electrodes deposited on the n-GaAs substrate, wherein each of the first set of electrodes comprises a plurality of metal layers; and a second electrode deposited on the p-GaAs layer.

In some embodiments, the n-GaAs substrate has a doping concentration less than or equal to 5×10¹⁷ cm⁻³, and the p-GaAs layer has a doping concentration less than or equal to 5×10¹⁷ cm⁻³; wherein the first set of electrodes comprises at least one of: palladium, germanium, silver, indium, copper, tin, and gold; wherein the second electrode comprises at least one of: gold, indium, and silver.

Additional embodiments and features are set forth in part in the description that follows, and in part will become apparent to those skilled in the art upon examination of the specification or may be learned by the practice of the disclosure. A further understanding of the nature and advantages of the present disclosure may be realized by reference to the remaining portions of the specification and the drawings, which forms a part of this disclosure.

### BRIEF DESCRIPTION OF THE DRAWINGS

The description will be more fully understood with reference to the following figures, which are presented as exemplary embodiments of the invention and should not be construed as a complete recitation of the scope of the invention. It should be noted that the patent or application file contains at least one drawing executed in color. Copies of this patent or patent application publication with color drawing(s) will be provided by the Office upon request and payment of the necessary fee.

FIGS. 1A and 1B illustrate III-V p-n junctions in an upright configuration in accordance with an embodiment.

FIGS. 1C and 1D III-V rear p-n junction configurations in accordance with an embodiment.

FIG. 2 illustrates a customized container for diffusion doping in accordance with an embodiment.

FIG. 3 illustrates a spalling process to form a semiconductor thin film in accordance with an embodiment.

FIG. 4A illustrates a spalled GaAs wafer (100) with intrinsic tooth-like patterns in accordance with prior art.

FIG. 4B illustrates a gold contact formed on a highly doped n-type GaAs contact layer in accordance with prior art.

FIG. 5 illustrates an epitaxy-free process of making a thin-film semiconductor device in accordance with an embodiment.

FIG. 6A illustrates a fabrication process of a thin-film solar cell in accordance with an embodiment.

FIG. 6B illustrates a thin-film GaAs solar cell in accordance with an embodiment.

FIG. 7 illustrates current-voltage response and photovoltaic parameters of cell in the dark and under AM 1.5G illumination in accordance with an embodiment.

FIG. 8 illustrates external quantum efficiency of diffusion doped and spalled GaAs solar cell in accordance with an embodiment.

FIG. 9 illustrates an epitaxy-free process of making a thin-film semiconductor device in accordance with an embodiment.

FIG. 10 illustrates a fabrication process of a thin-film solar cell in accordance with an embodiment.

FIG. 11 illustrates an epitaxy free fabrication process in accordance with an embodiment.

FIG. 12 illustrates current-voltage response and photovoltaic parameters of thin-film cell in the dark and under illumination in accordance with an embodiment.

FIG. 13 illustrates EQE of diffusion doped and spalled GaAs solar cell in accordance with an embodiment.

### DETAILED DESCRIPTION OF THE INVENTION

Low-cost (manufactured cost/Watt within one order-of-magnitude of that for terrestrial silicon photovoltaics), lightweight (density less than about 50 g/m²), efficient (efficiency greater than about 20%), and radiation-hard and environmentally robust (at least 15 years at geostationary orbit) solar cells are in need for special applications such as the use of solar cells in space. A commercial satellite may consume about 6 kW of electrical power during its life span. Conventional III-V space solar cells can cost about $100 per watt (W) for power production due to the costly epitaxy production processes that use vapor-phase growth techniques such as metal organic CVD (MOCVD) to create the optoelectronically active regions. Because of the high production cost, using conventional III-V space solar cells to power a commercial satellite can cost as much as $600,000. Therefor commercial satellites opt to use silicon solar cells. While the silicon solar cells have lower efficiency and narrower wavelength ranges than the III-V solar cells, they are much more cost effective (cost less than about $1 per W).

Commercial space III-V multijunction cells may be able to meet the demands of efficiency and radiation hardness, but are too heavy and too expensive due to costly epitaxy manufacturing processes. High efficiency experimental thin-film III-V solar cells may be able to form using epitaxial liftoff or spalling, but the high cost of epitaxy processes to grow the electrically-active device limits their applicability to large-scale applications such as space solar power. (See, e.g., G. J. Bauhuis, et al., Solar Energy Materials and Solar Cells, vol. 93, no. 9, 1488-1491, 2009; D. Shahrjerdi et al., Conference Record of the IEEE Photovoltaic Specialists Conference, 974-977, 2012; the disclosures of which are incorporated by reference.) Cost effective III-V solar cells with the desired weight, efficiency and radiation hardness are needed for space solar cell applications.

Many embodiments provide systems and methods for epitaxy-free thin-film devices with reduced production cost. Several embodiments use diffusion doping and mechanical spalling processes to make thin-film III-V solar cells. Diffusion doping can be a low-cost process to make optoelectronically functional p-n diode junctions (including heterojunctions). Controlled spalling can exfoliate thin films of material from a bulk crystal without expensive vapor-phase growth processes. In many embodiments, the epitaxy-free fabrication processes can form metal contacts such as Ohmic contacts on the p-n junctions and/or solar cells for extracting or injecting current. The epitaxy-free processes can fabricate thin-film devices such as (but not limited to) melt-growable semiconductors, single crystals of silicon, compound semiconductors, III-V semiconductors, p-n junctions, solar cells, III-V solar cells, amplifiers, and LEDs. Examples of III-V semiconductors and/or III-V solar cells can include (but are not limited to) gallium arsenide (GaAs), gallium phosphide (GaP), indium phosphide (InP), lead selenide (PbSe), lead telluride (PbTe), aluminum gallium arsenide (AlGaAs), AlInP, GaInP, GaAsP, and AlₓGa_{y}As_{z}Pₐ. The thin-film III-V solar cells can be fabricated using epitaxy-free processes. The epitaxy-free fabrication processes can eliminate the high cost associated with the vapor-phase growth techniques that are used for conventional III-V solar cells.

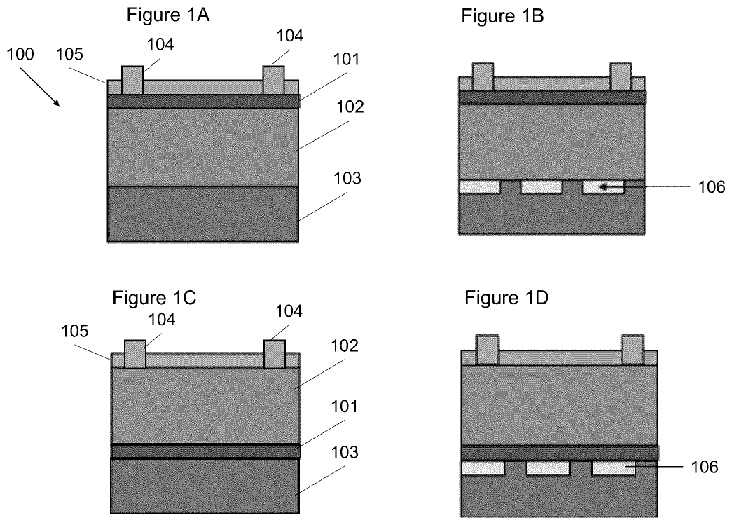

FIGS. 1A and 1B illustrate a III-V p-n junction in an upright configuration in accordance with an embodiment. FIGS. 1C and 1D a III-V rear p-n junction configuration in accordance with an embodiment. FIGS. 1B and 1D show that the dielectric spacers can be used to enhance the rear reflectivity of the solar cells with smaller metal/semiconductor interfaces for charge collection. A p-type III-V semiconductor layer 101 can be formed on an n-type III-V semiconductor substrate 102 via diffusion doping. A thin-film of the p-n junction 100 can be formed via spalling. A metal layer can be deposited on a first side of the p-n junction 100 to facilitate the spalling process (more details will be discussed later). In FIG. 1A, the metal layer 103 is deposited on the n-type III-V layer. In FIG. 1C, the metal layer 103 is deposited on the p-type III-V layer. Metal contacts 104 can be deposited on a second side of the p-n junction 100 for extracting or injecting current. In FIG. 1A, the metal contacts 104 are deposited on the p-type III-V layer. In FIG. 1C, the metal contacts 104 are deposited on the n-type III-V layer. An anti-reflection coating 105 can be deposited on the second side of the p-n junction 100. Dielectric spacers 106 can be deposited on the first side of the p-n junction 100 where the dielectric spacers 106 can enhance the rear reflectivity of the solar cells by creating smaller metal 103 and semiconductor (102 in FIG. 1B, 101 in FIG. 1D) interfaces for charge collection.

In many embodiments, various types of melt-growable semiconductors, p-n junctions, or III-V layers can be fabricated using the diffusion doping processes. During the diffusion doping process, the dopant atoms can be introduced from the gas phase of the dopant containing materials. The doping concentration may decrease from the surface. The in-depth distribution of the dopant can be determined by the temperature and/or pressure of the dopant, and the diffusion time. The diffusion doping processes eliminate the vapor phase growth needed for the epitaxy processes.

In many embodiments, various types of thin-film III-V semiconductor solar cells including (but not limited to) GaAs solar cells, InP solar cells, can be fabricated using the epitaxy-free processes. Various dopants including (but not limited to) zinc (Zn), cadmium (Cd), silicon (Si), germanium (Ge), tin (Sn), sulfur (S), selenium (Se), tellurium (Te), magnesium (Mg), can be used to make the electrically active p-n junctions of the solar cells. Zn and Cd doping can be used to fabricate p-doped layers in n-type GaAs, where Zn or Cd is a p-type dopant for GaAs. Zn or Cd diffusion doping can be used to fabricate p-doped layers in n-type InP, where Zn or Cd is a p-type dopant for InP.

During diffusion doping, the dopant materials can be heated up to reach a diffusion temperature. The dopant materials and the semiconductor substrates can be sealed in an inert environment during the heating and doping process. Many embodiments implement customized containers for diffusion doping. The customized containers can have friction seals such as stoppers to seal the containers. The containers can be made with refractory materials such as (but not limited to) ceramics, aluminum oxides, silicon oxides, and quartz. Several embodiments purge the containers with an inert gas to remove air and/or oxygen in the containers before diffusion doping. In several embodiments, the diffusion doping process can start as soon as oxygen is depleted from the container. The containers do not need to reach vacuum to start the diffusion doping processes. The containers can be placed in a tube furnace for the heating process.

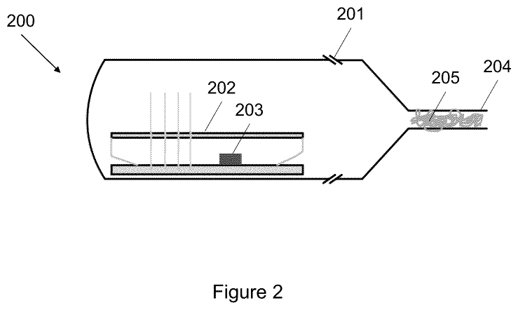

FIG. 2 illustrates a customized container for diffusion doping in accordance with an embodiment. The container 200 can be made with quartz or aluminum oxide, and can be various shapes (cylindrical, cubical, etc.) and volumes. The container 200 can be sealed with a friction seal 201 such as a quartz stopper. The sealable container can be reused for multiple times. A substrate 202 such as a semiconductor wafer (an n-type or a p-type semiconductor wafer, or an n-type GaAs substrate, or an n-type InP substrate) can be placed in the container. A dopant source material 203 (such as Zn or Cd) can be placed near the substrate (underneath the substrate, or below the substrate, or next to the substrate). A small opening 204 of the container 200 can be sealed with quartz wool 205, where inert gas back-filling can take place.

Many embodiments heat up the diffusion doping containers to a diffusion temperature. Appropriate temperature ranges can be selected for the dopant materials and the substrate. In several embodiments, the heating temperature can be greater than or equal to about 400° C.; or greater than or equal to about 500° C.; greater than or equal to about 600° C.; greater than or equal to about 700° C.; greater than or equal to about 800° C.; or from about 400° C. to about 450° C.; or from about 400° C. to about 550° C.; or from about 400° C. to about 650° C.; or from about 400° C. to about 750° C. A higher heating temperature can result in a higher concentration of doping. Temperatures between about 400° C. to about 550° C.; or at about 450° C. can be used to form the p-type GaAs layer on the n-type GaAs substrate using Zn as dopant in order to reach a desired doping concentration. Several embodiments control the diffusion time to control the doping concentration and/or depth. A longer diffusion time can lead to a higher doping concentration. In some embodiments, the pressure of the dopant materials can be controlled to reach a desired doping concentration. Zn or Cd can be dissolved in a solution to dilute the metal atoms in order to control the pressure.

The semiconductor thin films in accordance with some embodiments can be derived from bulk, melt-grown crystals. Several embodiments implement mechanical spalling to fabricate thin film III-V semiconductors from a bulk crystal by applying a stressed film. The thin films can have a thickness less than or equal to about 5 μm; or less than or equal to about 4 μm; or less than or equal to about 3 μm; or less than or equal to about 2 μm; or less than or equal to about 1 μm; or greater than or equal to about 100 nm; or greater than or equal to about 200 nm; or greater than or equal to about 300 nm; or greater than or equal to about 400 nm; or greater than or equal to about 500 nm. The thin films can have a variety of surface area of greater than or equal to about 500 mm by 500 mm; or greater than or equal to about 1 cm by 1 cm; or greater than or equal to about 5 cm by 5 cm; or greater than or equal to about 10 cm by 10 cm; or greater than or equal to about 50 cm by 50 cm; or greater than or equal to about 100 cm by 100 cm. In several embodiments, a stress film can be applied between the thin film and an adhesive tape. Various types of metals can be used as the stress films. The suitable metal films should form a strong enough intermetallic force between the semiconductor and the metal. The metal stress films should have strong mechanical properties such as Young's modulus, stress (greater than or equal to about 2 GPa). The stress film can be made with metal such as (but not limited to) nickel (Ni), chromium (Cr), or germanium (Ge). The metal stress films can be electroplated onto the semiconductor substrates. The stressor film should be under tensile stress. This can be an intrinsic property of the film, as with electroplated Ni, or it can be induced after the film is applied, in the case of cryogenic cooling, by exploiting the fact that tape has a greater coefficient of thermal expansion than GaAs. When the tape and GaAs are soaked in liquid nitrogen, the tape shrinks more than the GaAs and develops the appropriate stress for spalling.

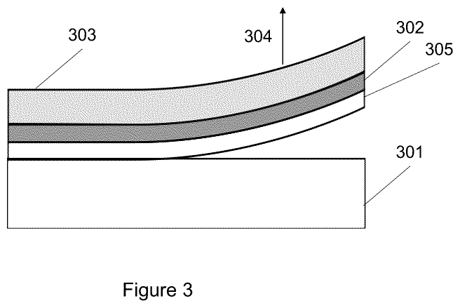

FIG. 3 illustrates a spalling process to form a semiconductor thin film in accordance with an embodiment. A III-V semiconductor substrate 301 such as a p-n junction can be formed via the diffusion doping process. A stress film 302 such as a metal film can be deposited or electroplated onto the III-V semiconductor substrate 301. The electroplated metal film (such as Ni or Cr film) can provide the stress for initiating the spalling process. An adhesive tape 303 can be attached to the metal stress film 302. The adhesive tape 303 can handle the spalled film and apply the crack formation force. An applied pulling force 304 can exfoliate (or spall) a thin film 305 off the III-V semiconductor substrate 301. The exfoliated (or spalled) thin film 305 has a thickness of less than or equal to about 5 μm. The exfoliated thin film 305 comprises the electrically active p-n junction, and can form the III-V solar cells. The thickness of the stress film 302 can affect the thickness of the thin films 305 as a result of the spalling process. Several embodiments provide that the adhesive tapes should have strong enough adhesive force to be applicable. In some embodiments, tapes with acrylic glues or silicone glues with stronger adhesive forces are preferred than the heat release tapes. Examples of adhesive tapes include (but are not limited to) Kapton tapes and silicone tapes.

Conventional epitaxy III-V solar cells include semiconductor layers that are grown on a substrate. Due to the epitaxy growth process, the substrate needs to have an orientation of (100). Substrates (or wafers) with (100) orientations are conventional or standard for epitaxy fabrication process. However, spalling the (100) substrates create intrinsic tooth like patterns. These tooth-like patterns can have heights ranging a few microns. These patterns are not desired in semiconductor devices such that additional processes (such as etching or polishing) are needed to remove the tooth-like patterns in order to achieve better performance in the solar cells. (See, e.g., K. Schulte, et al., Joule 7, 1529-1542, 2023; the disclosure of which is incorporated by reference.) In contrast to the epitaxial processes, the processes to make thin-film solar cells in accordance with many embodiments do not grow semiconductor layers on the wafer. Instead, the diffusion doping processes can dope the substrate by diffusing dopant vapors. The epitaxy-free processes in accordance with various embodiments eliminate the vapor phase growth processes such that wafer orientations other than (100) can be used for device fabrication. In several embodiments, wafers with orientations such as (110) can be used. The (110) wafer orientations do not create the tooth-like patterns during spalling such that the thin films have a uniform surface morphology free of corrugated patterns.

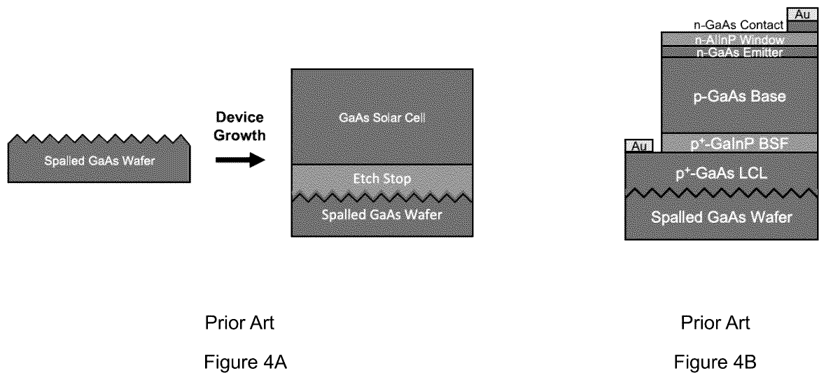

FIG. 4A illustrates a spalled GaAs wafer (100) with intrinsic tooth-like patterns. These tooth-like patterns need to be etched down so as to form a flat surface for device fabrication. The (100) orientation substrate is needed for growing semiconductor layers on top. In contrast, as the epitaxy free processes in accordance with many embodiments eliminate growing semiconductor layers on the substrate, substrates with (100) orientations may not be needed. Several embodiments are able to use substrate with (100) orientations and create flat surface via spalling, as shown in FIG. 3.

In many embodiments, metal contacts can be formed on the thin-film solar cells. In conventional epitaxy III-V solar cells, metal contacts are formed on a highly doped semiconductor layer (doping concentration of at least 5×10¹⁷ cm⁻³). Due to the conductive nature of the highly doped semiconductor layer, electrodes made of a single metal (such as gold, or platinum, or palladium) can be used to form an Ohmic contact with the underlying semiconductor layer. FIG. 4B illustrates a gold contact formed on a highly doped n-type GaAs contact layer. The semiconductor layers formed via diffusion doping and spalling have a relatively low doping concentration compared to the conventional epitaxially grown semiconductor layers. The doping concentration of the semiconductor layers in accordance with many embodiments are less than about 1×10¹⁸ cm⁻³; are less than about 5×10¹⁷ cm⁻³; or from about 5×10¹⁶ cm⁻³ to about 5×10¹⁷ cm⁻³; or less than or equal to about 5×10¹⁶ cm⁻³; or less than or equal to about 5×10¹⁵ cm⁻³; or less than or equal to about 5×10¹⁴ cm⁻³. Several embodiments use a plurality of metals in order to establish Ohmic contact with the semiconductor layers with lower doping concentrations. Examples of metal electrodes for the epitaxy-free thin-film solar cells include (but are not limited to) gold (Au), silver (Ag), indium (In), palladium/germanium/gold (Pd/Ge/Au), Pd/Ge/Ag, palladium/tin/silver (Pd/Sn/Ag), Pd/Sn/Au, and a combination thereof. The metal electrodes can be formed via metal deposition using a mask (such as a shadow mask, a metal mask) to define the electrode areas.

Many embodiments implement etch solvents that preferentially etch semiconductor substrate over the metal stress films. In some embodiments, the etch solvents can etch the GaAs substrate but not the nickel stress films. The etchant should be oxidizing and have a pH of at least 12, where nickel is passive and GaAs is corroded. The etch solvent can include a mixture of hydrogen peroxide and alkali hydroxide, as hydrogen peroxide and strong alkalis form a buffer system at pH about 12 so that the etchant may not corrode the nickel as long as sufficient peroxide is in the solution.

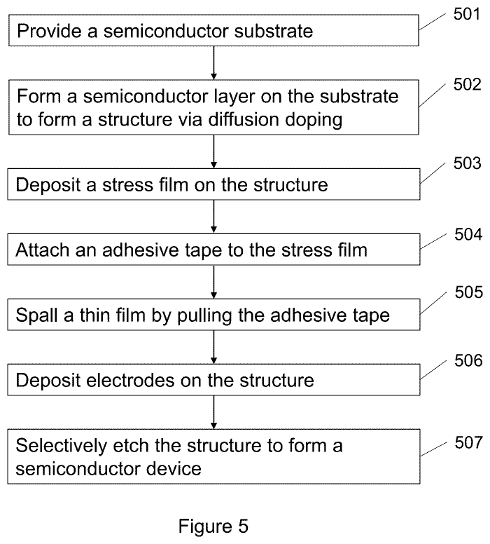

FIG. 5 illustrates an epitaxy-free process of making a thin-film semiconductor device in accordance with an embodiment. Provide (501) a semiconductor substrate as a base material to build a semiconductor device. The substrate can be a wafer, a semiconductor wafer, a slice, or a semiconductor slice. The substrate can be made of a semiconductor material (such as silicon, or germanium), or a compound semiconductor material (such as a III-V semiconductor). The substrate can be a p-type semiconductor or an n-type semiconductor, or an intrinsic semiconductor. As can be readily appreciated, any of a variety of semiconductor substrates can be utilized as appropriate to the requirements of specific applications in accordance with various embodiments of the invention. The substrate can have a variety of thickness of at least about 100 μm; or from about 100 μm to about 500 μm; or at least about 500 μm. The semiconductor substrate can have an orientation of (110) or (100). In several embodiments, the (110) orientation is preferred than the (100) for the spalling process, because spalling can create a flat and smooth surface with (110). (100) orientation may have corrugated surface patterns after spalling and may need further processing steps to smooth the surface.

Form (502) a semiconductor layer on the substrate to form a semiconductor structure via diffusion doping. Several embodiments use diffusion doping to avoid the costly vapor phase growth steps needed for epitaxy processes. The substrate can be sealed in an inert environment in a container with dopant source materials. The container can be heated up to a diffusion temperature for the dopant source materials. In some embodiments, customized containers that are made of refractory materials (such as ceramics, quartz, or aluminum oxide) can be used. The deposited semiconductor layer can form a junction structure with the substrate. In various embodiments, the semiconductor substrate can be n-type GaAs, and the deposited semiconductor layer can be p-type GaAs. In some embodiments, the semiconductor substrate can be p-type GaAs, and the deposited semiconductor layer can be n-type GaAs. In various embodiments, the semiconductor substrate can be n-type InP, and the deposited semiconductor layer can be p-type InP. In several embodiments, the semiconductor substrate can be p-type InP, and the deposited semiconductor layer can be n-type InP. As can be readily appreciated, any of a variety of semiconductor layers can be utilized as appropriate to the requirements of specific applications in accordance with various embodiments of the invention. The deposited semiconductor layers can have a variety of thickness of at least about 50 nm; or at least about 100 nm; or at least about 150 nm; or at least about 200 nm; or at least about 250 nm; or at least 500 nm; or at least 1 μm; or at least 2 μm. Various dopant materials (such as Zn or Cd) can be used during the diffusion doping processes. As can be readily appreciated, any of a variety of dopant materials can be utilized as appropriate to the requirements of specific applications in accordance with various embodiments of the invention.

Deposit (503) a stress film on the semiconductor structure. The stress film can provide the stress needed for initiating the spalling process. The stress film should have desired stress, and/or Young's modulus with the semiconductor material. The stress film can be deposited on the deposited semiconductor layer or the semiconductor substrate to form an upright configuration or a rear-junction configuration. The stress film can comprise a metal (such as nickel or chromium) in order to form intermetallic bonds with the semiconductor. The stress film can have a variety of thickness of at least 500 nm; or at least 1 μm; or at least 1.5 μm; or at least 2 μm.

Attach (504) an adhesive tape to the stress film. The tape should have strong enough adhesive force to endure the spalling process and to apply the crack formation force. The tape and the stress film stick together during spalling. The adhesive tape can be applied in a small scale (such as a chip) or in a large scale (such as a wafer). The tape can be applied manually or using a tape applicator.

Spall (505) a thin film from the semiconductor structure by pulling the adhesive tape. The pulling force exfoliates a thin film off the semiconductor structure. The thin film comprises the deposited semiconductor material and the semiconductor substrate such that the thin film can form a junction device. The thin film can have a variety of thickness of less than or equal to about 5 μm; or less than or equal to about 4 μm; or less than or equal to about 3 μm; or less than or equal to about 2 μm; or less than or equal to about 1 μm; or greater than or equal to about 100 nm; or greater than or equal to about 200 nm; or greater than or equal to about 300 nm; or greater than or equal to about 400 nm; or greater than or equal to about 500 nm.

Deposit (506) electrodes on the semiconductor structures to extract or inject current. As the semiconductors in the structure have relatively low doping concentration (lower than about 5×10¹⁷ cm⁻³), metal contacts comprising a variety of metals are deposited in order to form Ohmic contacts with the structure. Examples of metal contacts include (but are not limited to) Pd/Ge/Au, and Pd/Sn/Ag. Various methods can be used to deposit the metal contacts to the desired locations on the semiconductor structure, such as using a shadow mask. Annealing can be used to form the Ohmic contacts.

Selectively etch (507) the semiconductor structure to form a semiconductor device. The etch solvent is selected such that the semiconductor structure is etched through without etching the metal stress film. For a GaAs p-n junction on a Ni stress film, an etchant comprising hydrogen peroxide and alkali hydroxide can be used. The hydrogen peroxide and alkali hydroxide can form a buffer system at pH 12 so that the etchant may not corrode the nickel as long as sufficient peroxide is in the solution.

### Epitaxy-Free Thin-Film GaAs Solar Cell

Many embodiments provide scalable processes for ultralight thin-film III-V solar cell fabrication without the use of epitaxy. These cells demonstrate the viability of combining the cost-saving techniques of diffusion doping to create p-n junctions and spalling to derive thin-films from bulk crystals. The fabrication processes remove the high-cost epitaxy processes of III-V cell fabrication.

Many embodiments provide thin-film GaAs solar cells without epitaxial growth. To fabricate the cell, several embodiments create a p-n junction by zinc diffusion to realize p-type doping in bulk n-type crystals. A thin film of GaAs that includes the p-n junction on an electroplated nickel backing layer directly deposited onto the diffusion doped p-GaAs can be formed via spalling. The electroplated nickel serves as a mechanical handle layer and rear electrical contact. A Pd/Ge/Au top contact becomes Ohmic after a 180° C. anneal, a process which is compatible with the nickel and tape handling layers. Under AM 1.5G illumination the cell can achieve an open circuit potential (V_{oc}) of at least about 850 mV; or about 856 mV, and a power of about 500 W/kg at a mass density of about 32 g/m² can be achieved including the metal and GaAs.

Several embodiments provide the fabrication and characterization of thin-film, epitaxy-free GaAs solar cells made by combining diffusion doping to make a p-n junction and then using mechanical spalling to exfoliate the thin film GaAs cell, including the p-n junction, from a bulk wafer. By eliminating epitaxy and potentially being able to derive many cells from the same GaAs bulk crystal, these devices show a scalable low-cost process for reducing both the levelized cost of energy (LCOE) and capital intensity of III-V photovoltaics while maintaining their durability and photovoltaic performance.

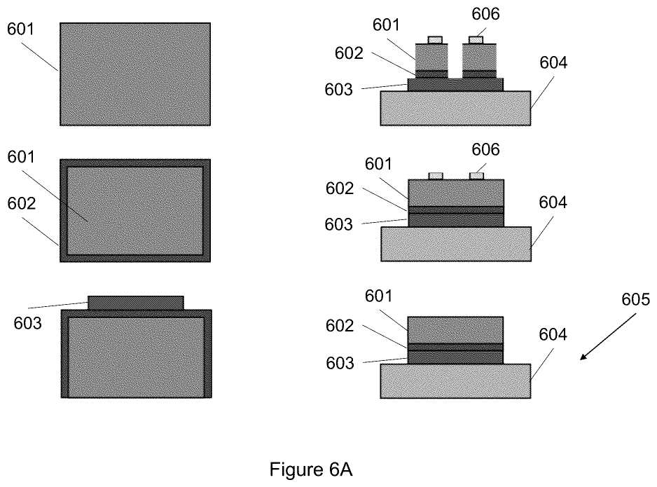

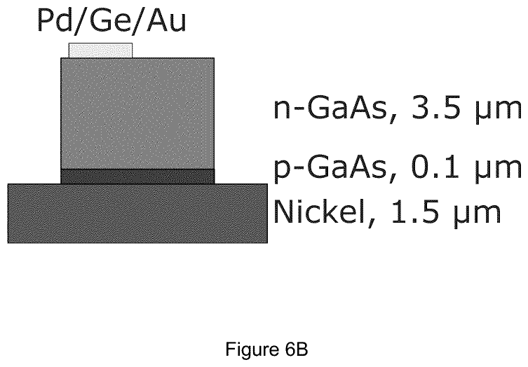

FIG. 6A illustrates a fabrication process of a thin-film GaAs solar cell in accordance with an embodiment. In the fabrication process, each subsequent step would not disturb the chemical or mechanical properties of the previous. By performing the diffusion before the spalling, many embodiments ensure that the GaAs and Ni cannot react to degrade and consume the GaAs. This consideration may limit the n-type ohmic contact choice to Pd/Ge/Au, which can become ohmic with anneals below 200° C. and is therefore compatible with preserving the Ni/GaAs interface and the tape used as the overall mechanical handle. Because the handle layer used during fabrication becomes the backing layer and rear contact, the device has a rear junction configuration.

Device fabrication begins with a (110) oriented GaAs chip 601 with an electron concentration of about 2*10¹⁷ cm⁻³. The GaAs chip 601 has a thickness of about 500 μm. Several embodiments use (110) oriented substrates so that the spalled surface will be smooth. The surface of the chip is doped with zinc by annealing in a closed alumina crucible with zinc metal at about 475° C. for about 90 minutes under forming gas ambient. The resulting p-type layer 602 has a mobility of about 65 cm²/(V s), carrier concentration of about 1.7*10¹⁴ cm⁻², sheet resistance of about 500 Ω/□, and a depth of about 150 nm as measured by spreading resistance. After diffusion doping, nickel 603 with about 5 mm diameter aperture can be electroplated via electroplating jig and a solution of 0.6 M nickel chloride hexahydrate and 5 mM phosphorous acid solution at about 45° C. Plating occurs at about 10 mA/cm² for 12 minutes to achieve nickel thicknesses of about 1.5 μm. The thickness of electroplated nickel is confirmed through profilometry. Several embodiments exfoliate the Ni/GaAs bilayer by applying a Kapton tape 604 to the exposed nickel face before attaching the Kapton tape to a mechanical roller. The spall can be initiated and controlled through manually rolling over the surface, resulting in a continuous bilayer film adhered to the tape 605. The tape is then secured to a glass slide for further device fabrication. The GaAs film adhered to the nickel is approximately 3.5 μm thick. The nickel serves as the ohmic back contact to the solar cell. Transmission line measurements of Ni evaporated onto similarly prepared p-GaAs layers yield a contact resistance of about 0.5 Ωcm².

The front contacts 606 can be formed by sequentially evaporating Pd (10 nm)/Ge (35 nm)/Au (100 nm) and annealing under nitrogen at about 180° C. for about one hour. The front contacts area can be defined using a shadow mask.

Several embodiments then isolate the cells using photolithographically defined mesas. The etchant for mesa isolation is a one-to-one volume ratio of 1M NaOH and 30% H₂O₂ that etches GaAs at about 2 μm/min. This chemistry is convenient because the concentration of peroxide being greater than the alkali buffers the pH to approximately 12 so that the GaAs is etched but the Ni is passive.

FIG. 6B illustrates a thin-film GaAs solar cell in accordance with an embodiment. The solar cell is formed via an epitaxy free process. The nickel layer is about 1.5 μm in thickness, the diffusion doped p-GaAs layer is about 0.1 μm in thickness, the n-GaAs is about 3.5 μm in thickness. The nickel acts as the back contact. The front contact comprises Pd, Ge, and Au.

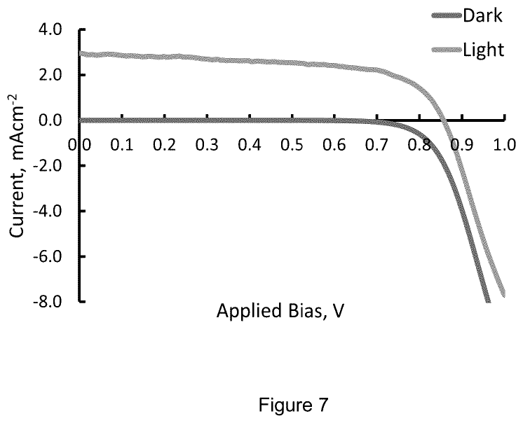

Several embodiments provide the AM 1.5G and dark current-voltage response of a device after a brief etch to remove oxide. FIG. 7 illustrates current-voltage response and photovoltaic parameters of cell in the dark and under AM 1.5G illumination after a brief etch to remove oxide in accordance with an embodiment. In the dark, the cell is free from shunts and has a series resistance of about 16 Ωcm². Under AM 1.5G illumination, the cell has a short circuit current density J_{sc} of about 3.0 mAcm⁻², open circuit potential (V_{oc}) of about 857 mV, fill factor (FF) of about 61%, and overall efficiency of about 1.6%. Including the mass of the nickel and GaAs over the active device area, a specific power of about 500 W/kg at this low efficiency can be achieved. By boosting the efficiency to 20% the specific power would be about 6.2 kW/kg There is also an apparent shunt may be an artifact of carrier collection improving at reverse bias due to the depletion region widening. By reducing light intensity, a suns-V_{oc} ideality of factor of 1.6 can be measured, indicating the junction is not limiting cell performance.

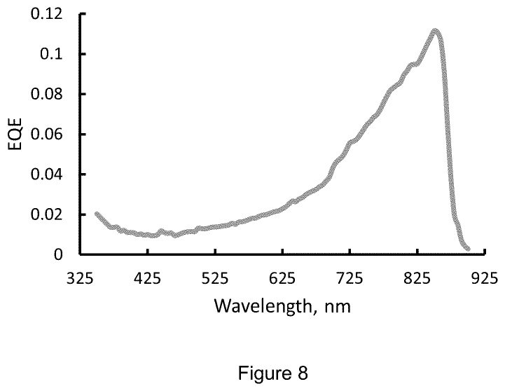

FIG. 8 illustrates external quantum efficiency (EQE) of diffusion doped and spalled GaAs solar cell in accordance with an embodiment. The less than 10% quantum efficiency for short wavelengths indicates the poor hole diffusion length of commercially available n-GaAs. The hole diffusion length of commercially available bulk GaAs is about 0.5 μm, which is much shorter than the 3.5 μm thickness of the cell. The performance of the cell may be improved by using n-GaAs with longer hole diffusion lengths. Device physics modeling suggests that a 1.5 μm thick cell with a 10 μm hole diffusion length, silver mirror, and 1,000 cm/s surface recombination velocity can achieve a J_{sc} of about 30.3 mAcm⁻². To improve performance, some embodiments may fabricate front-junction devices so that more light is absorbed near the p-n junction. Several embodiments may improve the large series resistance by determining if it is due to one of the metal contacts, conduction through the GaAs, or an artifact of the poor contact design of our existing prototype. Some embodiments may implement lower cost contacts. Evaporation and gold may not be compatible with low-cost cell fabrication, so electroplated contacts that attempt to preserve the low-temperature processing metallurgy of the Pd/Ge/Au contact may be implemented.

### Epitaxy-Free Thin-Film Semiconductor Device

In many embodiments, a thin film semiconductor junction structure can be formed via diffusion doping and spalling. In several embodiments, nickel can be used as a stress film during the spalling process to provide the mechanical support to form the thin film structure. In various embodiments, the nickel film can be patterned and used as top electrodes.

In a number of embodiments, the nickel film can be removed to improve the semiconductor device's qualities. After depositing the top electrodes (such as Pd/Ge/Au electrodes), the top electrodes can be annealed to form Ohmic contacts with the semiconductor layers. Removing the nickel ensures that nickel will not degrade the semiconductor layers (such as GaAs) during the contact anneal processes. A second tape can be attached to the top electrodes. The second tape can have a higher adhesive force than the tape used for spalling. Examples of the second tape can include (but are not limited to) Kapton tapes with silicon adhesives. Examples of the tape used for spalling include (but are not limited to) heat-release tapes, tapes with water soluble adhesives, and UV-release tapes. Several embodiments remove the tape used for spalling by peeling the second tape. Peeling the second tape exposes the stress film (such as nickel) as a top film. Nickel can be removed via chemical etching such as (but not limited to) Transene® Ni TFG. The appropriate nickel etchant should be selected as it etches nickel but not the semiconductor materials (such as GaAs or InP) nor the second tape. Nickel etchants such as nitric acid may not work as it attacks GaAs. Nickel etchants such as hydrochloric and sulfuric acids may not work as they attack the tape adhesive. Removing the stress films (such as nickel) can increase the choices of the electrodes as the stress films may react with the semiconductors during annealing. Without the stress film, the annealing temperature can be any temperature that is tolerable with the adhesives of the second tape. For Kapton tapes with silicone adhesive, the anneal temperature limit can be less than or equal to about 400° C. in inert gas. The enhanced anneal temperature can allow for electrodes such as (but not limited to) CuGe, Au/Ag/Sn, Pd/Ge/Au, Pd/Sn/Ag as the n-type Ohmic contact. Certain embodiments can swap the face-up side of the GaAs arbitrarily a number of times by using tapes with orthogonal release mechanisms. Some embodiments can do so by alternating between tapes with different release mechanisms.

In several embodiments, the electrodes that are deposited on the doped semiconductor layers (such as the electrodes on n-type GaAs) and the second tape work to keep the semiconductor layers (such as GaAs layers) under compressive stress. The semiconductor layers can be weak under tension and tend to crack. As the nickel layer is etched, the GaAs loses its biaxial compression from the nickel, and so the metal electrodes and the second tape on the opposite side of the nickel are now under biaxial tension as the nickel is lost and the GaAs expands. It's important that the metal electrodes and the second tape can be strong enough to take up this tension without breaking, which can be achieved by making the metal electrode and the second tape thick enough.

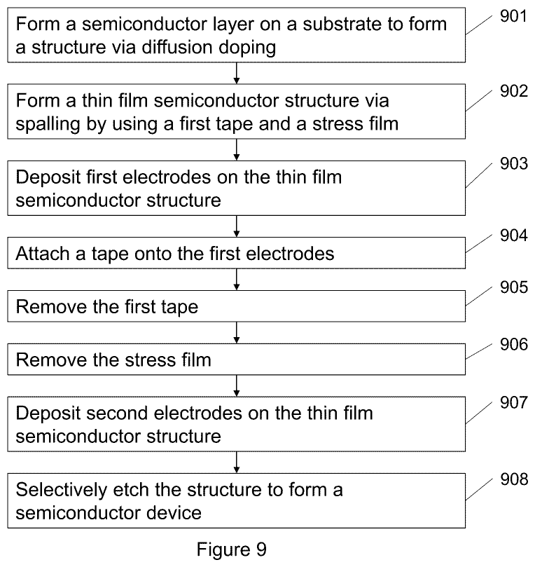

FIG. 9 illustrates an epitaxy-free process of making a thin-film semiconductor device in accordance with an embodiment. Form (901) a semiconductor layer on a substrate to form a semiconductor structure via diffusion doping. A semiconductor substrate such as (but not limited to) a wafer, a semiconductor wafer, a slice, or a semiconductor slice can be used as a base material to build the semiconductor device. The substrate can comprise a semiconductor material (such as silicon, or germanium), or a compound semiconductor material (such as a III-V semiconductor). The substrate can be a p-type semiconductor or an n-type semiconductor, or an intrinsic semiconductor. As can be readily appreciated, any of a variety of semiconductor substrates can be utilized as appropriate to the requirements of specific applications in accordance with various embodiments of the invention. The substrate can have a variety of thickness of at least about 100 μm; or from about 100 μm to about 500 μm; or at least about 500 μm. The semiconductor substrate can have an orientation of (110) or (100). In several embodiments, the (110) orientation is preferred than the (100) for the spalling process. Several embodiments use diffusion doping to deposit a doped semiconductor layer on the substrate. The diffusion doping process can avoid the costly vapor phase growth steps needed for epitaxy processes. The deposited semiconductor layer can form a junction structure with the substrate. In various embodiments, the semiconductor substrate can be n-type GaAs, and the deposited semiconductor layer can be p-type GaAs. In some embodiments, the semiconductor substrate can be p-type GaAs, and the deposited semiconductor layer can be n-type GaAs. In various embodiments, the semiconductor substrate can be n-type InP, and the deposited semiconductor layer can be p-type InP. In several embodiments, the semiconductor substrate can be p-type InP, and the deposited semiconductor layer can be n-type InP. As can be readily appreciated, any of a variety of semiconductor layers can be utilized as appropriate to the requirements of specific applications in accordance with various embodiments of the invention. The deposited semiconductor layers can have a variety of thickness of at least about 50 nm; or at least about 100 nm; or at least about 150 nm; or at least about 200 nm; or at least about 250 nm; or at least 500 nm; or at least 1 μm; or at least 2 μm. Various dopant materials (such as Zn or Cd) can be used during the diffusion doping processes. As can be readily appreciated, any of a variety of dopant materials can be utilized as appropriate to the requirements of specific applications in accordance with various embodiments of the invention.

Form (902) a thin film semiconductor structure via spalling. Deposit a stress film on the semiconductor structure. The stress film can provide the stress needed for initiating the spalling process. The stress film can be deposited on the deposited semiconductor layer or the semiconductor substrate to form an upright configuration or a rear-junction configuration. The stress film can comprise a metal (such as nickel or chromium) to form intermetallic bonds with the semiconductor. The stress film can have a variety of thickness of at least 500 nm; or at least 1 μm; or at least 1.5 μm; or at least 2 μm. Attach a first adhesive tape to the stress film. The tape should have strong enough adhesive force to endure the spalling process and to apply the crack formation force. The first tape and the stress film stick together during spalling. The adhesive tape can be applied in a small scale (such as a chip) or in a large scale (such as a wafer). The tape can be applied manually or using a tape applicator. The thin film semiconductor structure can be formed by pulling the first adhesive tape. The pulling force exfoliates a thin film off the semiconductor structure. The thin film comprises the deposited semiconductor material and the semiconductor substrate where the thin film forms a junction device. The thin film can have a variety of thickness of less than or equal to about 5 μm; or less than or equal to about 4 μm; or less than or equal to about 3 μm; or less than or equal to about 2 μm; or less than or equal to about 1 μm; or greater than or equal to about 100 nm; or greater than or equal to about 200 nm; or greater than or equal to about 300 nm; or greater than or equal to about 400 nm; or greater than or equal to about 500 nm.

Deposit (903) a first set of electrodes on the thin film semiconductor structure. As the semiconductors in the structure have relatively low doping concentration (lower than about 5×10¹⁷ cm⁻³), metal contacts comprising a variety of metals are deposited in order to form Ohmic contacts with the structure. Examples of metal contacts include (but are not limited to) Pd/Ge/Au, and Pd/Sn/Ag. Various methods can be used to deposit the metal contacts to the desired locations on the semiconductor structure, such as using a shadow mask.

Attach (904) a second tape onto the first set of electrodes. The second tape can have a higher adhesive force than the first tape. Examples of the second tape can include (but are not limited to) Kapton tapes with silicon adhesives. Examples of the first tape include (but are not limited to) heat-release tapes, tapes with water soluble adhesives, and UV-release tapes. Remove (905) the first tape by peeling the second tape. Peeling the second tape exposes the stress film (such as nickel) as a top film. Remove (906) the stress film using a chemical etching process. As the stress film (such as the nickel layer) is etched, the semiconductor layers (such as GaAs) lose their biaxial compression force from the nickel, and so the first set of electrodes and the second tape on the opposite side of the nickel are now under biaxial tension as the nickel is lost and the GaAs expands. The first set of electrodes and the second tape should be thick enough to bear the tension force without breaking when etching away the stress film. The stress film can be removed via various chemical etchants. The propriate etchant should be selected as it etches the stress film but not the semiconductor materials (such as GaAs or InP) nor the second tape. Removing the stress films (such as nickel) can increase the choice of metals and/or metal alloys for the first set of electrodes as the stress films may react with the semiconductors during annealing. Without the stress film, the annealing temperature can be any temperature that is tolerable with the adhesives of the second tape. For an anneal temperature less than or equal to about 400° C. in inert gas, the first set of electrodes can be (but are not limited to) CuGe, Au/Ag/Sn, Pd/Ge/Au, Pd/Sn/Ag as the n-type Ohmic contact.

Deposit (907) a second set of electrodes onto the semiconductor structures after removing the stress film. The second set of electrodes can be any metals and/or metal alloys such as (but not limited to) Au, Pd, Ge, Cu, Pt, Ag, Sn, Ge, CuGe, Au/Ag/Sn, Pd/Ge/Au, and Pd/Sn/Ag. Various methods can be used to deposit the metal contacts to the desired locations on the semiconductor structure, such as using a shadow mask.

Selectively etch (908) the semiconductor structure to form a semiconductor device. The etch solvent is selected such that the semiconductor structure is etched through without etching the semiconductor materials.

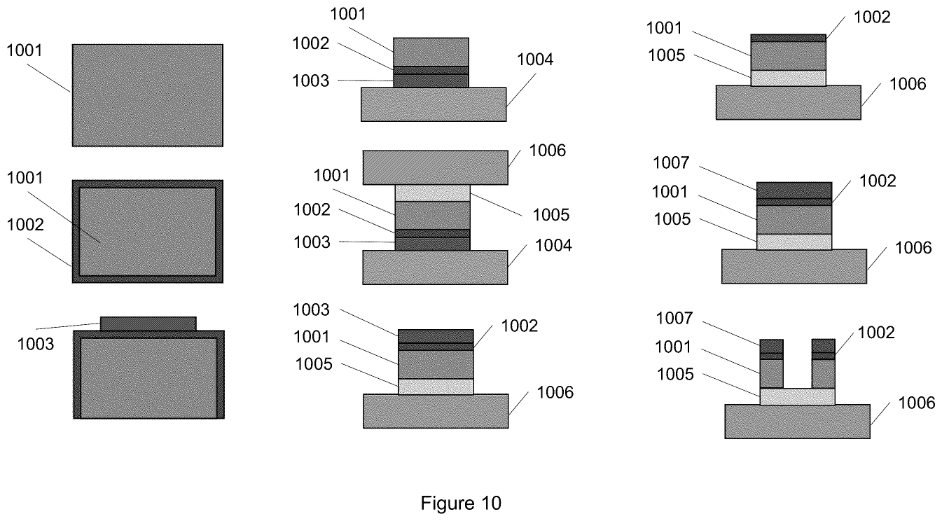

FIG. 10 illustrates a fabrication process of a thin-film GaAs solar cell in accordance with an embodiment. In the fabrication process, each subsequent step would not disturb the chemical or mechanical properties of the previous. By performing the diffusion before the spalling, many embodiments ensure that the semiconductor and the stress film cannot react to degrade and consume the semiconductor. By using a second tape to remove the stress film, several embodiments can allow for a wider range of annealing temperatures. The enhanced annealing temperature ranges enable various n-type ohmic contact choices such as (but not limited to) CuGe, Au/Ag/Sn, Pd/Ge/Au, Pd/Sn/Ag.

Device fabrication begins with a (110) oriented GaAs chip 1001 with an electron concentration of less than or equal to about 5*10¹⁷ cm⁻³. The GaAs chip 1001 has a thickness of less than or equal to about 500 μm. Several embodiments use (110) oriented substrates so that the spalled surface will be smooth. The surface of the chip is doped with zinc by annealing with zinc metal in an inert environment. The resulting p-type layer 1002 has a carrier concentration of less than or equal to about 5*10¹⁵ cm⁻². After diffusion doping, nickel 1003 can be electroplated or deposited onto the doped GaAs. The nickel layer can have a thickness of less than or equal to about 2 μm. Several embodiments exfoliate the Ni/GaAs bilayer by applying a first tape 1004 to the exposed nickel face. The spall can be initiated and controlled through manually rolling over the surface, resulting in a continuous bilayer film adhered to the tape. A first set of electrodes 1005 can be deposited onto the GaAs layer 1001. Some embodiments attach a second tape 1006 to the first set of electrodes 1005. Remove the first tape 1004 such that the stress film 1003 is the top layer and the second tape 1006 is the substrate. Remove the stress film 1003 using a chemical etchant. Deposit a second set of electrodes 1007 onto the doped GaAs layer 1002. Anneal the structure so the first set of electrodes 1005 and the second set of electrodes 1007 become ohmic contacts. Remove part of the electrodes and semiconductor layers to isolate and form the semiconductor devices. The first set of electrodes 1005 can serve as the back contacts and the second set of electrodes 1007 can serve as the top electrodes.

Several embodiments implement diffusion doping for making p/n junctions and controlled spalling for exfoliating thin films of material from a bulk crystal to fabricate a thin-film III-V cell without epitaxy. Some embodiments provide thin-film, epitaxy-free GaAs solar cells made by combining diffusion doping to make a p/n junction and then using mechanical spalling to exfoliate a thin-film of GaAs that includes the p/n junction from a bulk wafer. By eliminating epitaxy and potentially being able to derive many cells from the same wafer these devices demonstrate a novel strategy for reducing both the LCOE and capital intensity of III-V photovoltaics while maintaining their durability and photovoltaic performance.

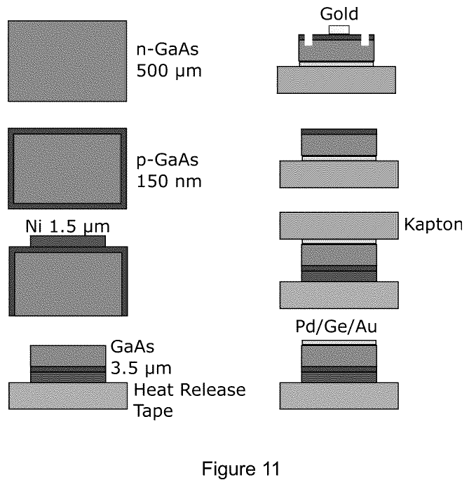

FIG. 11 illustrates an epitaxy free fabrication process in accordance with an embodiment. Several embodiments ensure that each subsequent step would not disturb the chemical or mechanical properties of the previous. By removing the nickel before annealing the Pd/Ge/Au electrodes, the fraction of contacts that become ohmic can be improved. The compressive stress in the GaAs from the nickel stressor layer may suppress germanium doping during the contact reaction.

Device fabrication begins with a (110) oriented GaAs wafer with an electron concentration of about 5*10¹⁶ cm⁻³. (110) oriented substrates are used because the spalled surface will be smooth. The surface of the chip is doped with zinc by annealing it in a closed alumina crucible with zinc metal at about 450° C. for 120 minutes under forming gas ambient, followed by an anneal at 400° C. open to forming gas to enhance zinc activation. The resulting p-type layer has a mobility of about 65 cm²/(V s), carrier concentration about 1.7*10¹⁴ cm⁻², sheet resistance 500 Ω/□, and a depth of 150 nm as measured by spreading resistance. After diffusion doping, nickel can be electroplated with a 40 mm diameter aperture electroplating jig and a solution of 0.6 M nickel chloride hexahydrate and 5 mM phosphorous acid solution at 50° C. Plating occurs at 10 mA/cm² for approximately 20 minutes to achieve nickel thicknesses of 1.5 μm. The Ni/GaAs bilayer can then be exfoliated by laminating a heat-release tape to the exposed nickel face before attaching the tape to a roller for spalling. After spalling, the tape can be secured to a glass slide for further device fabrication. The GaAs film adhered to the nickel is approximately 3.5 μm thick. The spalling reveals n-GaAs. A first set of electrodes Pd (10 nm)/Ge (50 nm)/Au (50 nm) can be evaporated onto n-GaAs. The first set of electrodes can function as the back ohmic contact. A 2.5 millimeter thick Kapton tape with silicone adhesive can be adhered onto the Au, which will serve as the permanent mechanical handle. The laminated stack can be placed on a hot place to remove the heat-release tape. The stack can be secured to a glass slide, and then the films can be annealed in a tube furnace under forming gas at about 180° C. for two hours to activate the PdGeAu contacts. The nickel stress film can be removed by etching in stirred Transene Ni TFG etchant at 50° C. Finally, 1 nm Ti/100 nm Au front contacts and mesa isolation can be defined using photolithographic, lift-off, and wet-etching techniques.

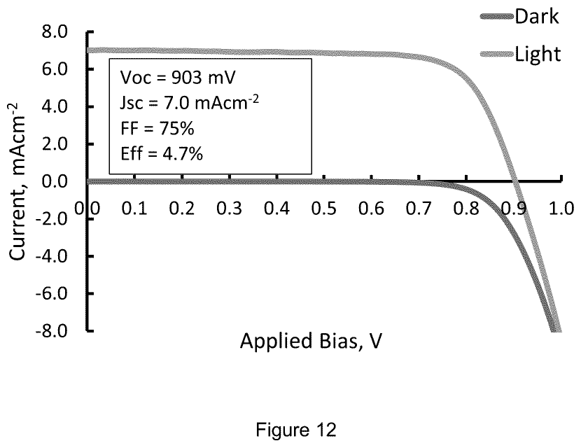

FIG. 12 illustrates current-voltage response and photovoltaic parameters of thin-film cell in the dark and under illumination in accordance with an embodiment. FIG. 12 shows the AM 1.5g and dark current-voltage response of the device. In the dark, the cell is free from shunts and has an ideality factor of 1.9 due to the high concentration of the EL2 defect in commercially available, bulk, GaAs. Under AM 1.5g illumination, the cell has a J_{sc} of 7.0 mAcm⁻², V_{oc} 906 mV, FF 75%, and overall efficiency of 4.7%. Including the mass of the metal, Kapton tape, and GaAs over the active device area, a power of about 500 W/kg can be achieved. By boosting the efficiency to 20% the specific power would be 2 kW/kg.

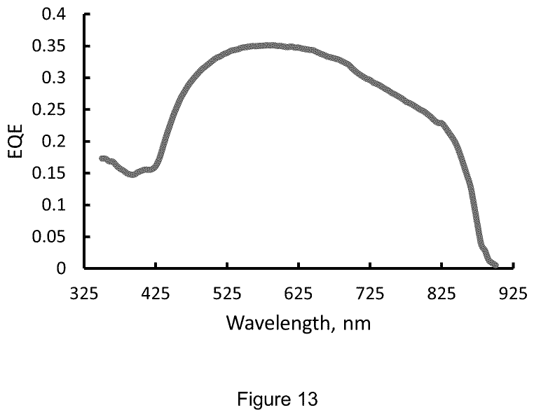

FIG. 13 illustrates EQE of diffusion doped and spalled GaAs solar cell in accordance with an embodiment. The weak long-wavelength response indicates the short hole diffusion length of the commercial, bulk n-GaAs. The poor IQE in the red indicates the poor hole diffusion length of commercially available n-GaAs. The hole diffusion length of commercially available bulk GaAs is about 0.5 μm, which is much shorter than the 3.5 μm thickness of the cell. The EQE of the cell integrates to 9 mAcm⁻², which is greater than the measured 7, maybe due to cracks in the cell.

The epitaxy-free, thin-film, upright-junction, III-V solar cells show the viability of combining the cost-saving techniques of diffusion doping to create p/n junctions and spalling to derive thin-films from bulk crystals which, taken together, remove the high-cost epitaxy processes of III-V cell fabrication. Some embodiments can improve performance by using n-GaAs with longer hole diffusion lengths. In some embodiments, a 1.5 μm thick cell with a 10-micron hole diffusion length and silver mirror can achieve a J_{sc} of 30.3 mAcm⁻². In some embodiments, annular rings of GaAs may appear during spalling, suggesting the thickness of the Ni is non-uniform, with thicker Ni at the edges due to current crowding and the limited lateral conductivity of p-GaAs on an inch length scale. Some embodiments may implement seed layers of plating apertures to enhance plated film uniformity.

### Doctrine of Equivalents

As can be inferred from the above discussion, the above-mentioned concepts can be implemented in a variety of arrangements in accordance with embodiments of the invention. Accordingly, although the present invention has been described in certain specific aspects, many additional modifications and variations would be apparent to those skilled in the art. It is therefore to be understood that the present invention may be practiced otherwise than specifically described. Thus, embodiments of the present invention should be considered in all respects as illustrative and not restrictive.

As used herein, the singular terms “a,” “an,” and “the” may include plural referents unless the context clearly dictates otherwise. Reference to an object in the singular is not intended to mean “one and only one” unless explicitly so stated, but rather “one or more.”

As used herein, the terms “approximately,” and “about” are used to describe and account for small variations. When used in conjunction with an event or circumstance, the terms can refer to instances in which the event or circumstance occurs precisely as well as instances in which the event or circumstance occurs to a close approximation. When used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Additionally, amounts, ratios, and other numerical values may sometimes be presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified. For example, a ratio in the range of about 1 to about 200 should be understood to include the explicitly recited limits of about 1 and about 200, but also to include individual ratios such as about 2, about 3, and about 4, and sub-ranges such as about 10 to about 50, about 20 to about 100, and so forth.

What is claimed is:

1. A method for fabricating a semiconductor device comprising:
forming a semiconductor layer on a semiconductor substrate via a diffusion doping process, wherein the semiconductor layer and the semiconductor substrate forms a p-n junction;
depositing a stress film on the semiconductor layer;
exfoliating a thin film by applying a pulling force to the stress film, wherein the thin film comprises the semiconductor layer and at least a portion of the semiconductor substrate;
depositing at least one electrode on the thin film to form an ohmic contact; and
etching a portion of the exfoliated thin film while preserving the stress film and the at least one electrode to form a semiconductor device.

2. The method of claim 1, wherein the semiconductor substrate comprises a material selected from the group consisting of: silicon, germanium, a III-V semiconductor, GaAs, GaP, InP, AlGaAs, GaInP, and GaAsP.

3. The method of claim 1, wherein the semiconductor substrate has a (110) orientation.

4. The method of claim 1, wherein the semiconductor substrate comprises an n-type semiconductor, and the semiconductor layer comprises a p-type semiconductor.

5. The method of claim 1, wherein the semiconductor substrate comprises a p-type semiconductor, and the semiconductor layer comprises an n-type semiconductor.

6. The method of claim 1, wherein the stress film comprises a metallic material selected from the group consisting of: nickel, chromium, and germanium.

7. The method of claim 1, wherein the thin film has a thickness less than or equal to 5 μm.

8. The method of claim 1, further comprising applying an adhesive tape to the stress film and pulling the adhesive tape to exfoliate the thin film.

9. The method of claim 8, wherein the adhesive tape comprises an acrylic glue or a silicone glue.

10. The method of claim 1, wherein the semiconductor substrate has a doping concentration less than or equal to 5×10¹⁷ cm⁻³; wherein the semiconductor layer has a doping concentration less than or equal to 5×10¹⁷ cm⁻³.

11. The method of claim 1, wherein the at least one electrode comprises a plurality of metal layers.

12. The method of claim 11, wherein the at least one electrode comprises at least one of: palladium, germanium, silver, indium, copper, tin, and gold.

13. The method of claim 1, wherein the diffusion doping process uses a sealed container with an inert gas; wherein the container comprises a refractory material.

14. The method of claim 1, further comprising annealing the at least one electrode to a temperature less than or equal to 200° C. to form the ohmic contact.

15. The method of claim 1, wherein the semiconductor substrate comprises n-GaAs, and the semiconductor layer comprises p-GaAs; wherein the diffusion doping processes uses a material comprising Zn as a dopant; wherein the stress film comprises nickel; wherein the at least one electrode comprises palladium, germanium, and gold.

16. The method of claim 15, wherein the etching step uses an etch solution comprising hydrogen peroxide and alkali hydroxide.

17. The method of claim 15, wherein the semiconductor device has an open circuit potential of at least 850 mV.

18. The method of claim 8, further comprising applying a second adhesive tape to the at least one electrode; removing the adhesive tape; and removing the stress film; and depositing a second set of electrodes onto the thin film.

19. A solar cell comprising:
an n-gallium arsenide (GaAs) substrate with a (110) orientation;
a p-GaAs layer forming a junction with the n-GaAs substrate, wherein a thickness of the n-GaAs substrate and the p-GaAs layer is less than or equal to 5 μm;
a plurality of electrodes deposited on the n-GaAs substrate, wherein each of the plurality of electrodes comprises a plurality of metal layers; and
at least one electrode deposited on the p-GaAs layer.

20. The solar cell of claim 19, wherein the n-GaAs substrate has a doping concentration less than or equal to 5×10¹⁷ cm⁻³, and the p-GaAs layer has a doping concentration less than or equal to 5×10¹⁷ cm⁻³; wherein the plurality of electrodes comprises at least one of: palladium, germanium, silver, indium, copper, tin, and gold; wherein the at least one electrode comprises at least one of: nickel, germanium, and chromium.

21. A solar cell comprising:
an n-gallium arsenide (GaAs) substrate with a (110) orientation;
a p-GaAs layer forming a junction with the n-GaAs substrate, wherein a thickness of the n-GaAs substrate and the p-GaAs layer is less than or equal to 5 μm;
a first set of electrodes deposited on the n-GaAs substrate, wherein each of the first set of electrodes comprises a plurality of metal layers; and
a second electrode deposited on the p-GaAs layer.

22. The solar cell of claim 21, wherein the n-GaAs substrate has a doping concentration less than or equal to 5×10¹⁷ cm⁻³, and the p-GaAs layer has a doping concentration less than or equal to 5×10¹⁷ cm⁻³; wherein the first set of electrodes comprises at least one of: palladium, germanium, silver, indium, copper, tin, and gold; wherein the second electrode comprises at least one of: gold, indium, and silver.
